(19) United States
(12) Patent Application Publication
(10) Pub. No.: US 2026/0156783 A1
(43) Pub. Date: Jun. 4, 2026

(54) OPTICAL TRANSCEIVER MODULE HOUSING AND OPTICAL TRANSCEIVER MODULE

(71) Applicant: ALL BEST PRECISION TECHNOLOGY CO., LTD., TAOYUAN CITY (TW)

(72) Inventor: Haven Yang, TAOYUAN CITY (TW)

(73) Assignee: ALL BEST PRECISION TECHNOLOGY CO., LTD., TAOYUAN CITY (TW)

(21) Appl. No.: 18/988,952

(22) Filed: Dec. 20, 2024

(30) Foreign Application Priority Data
Nov. 29, 2024 (TW) 113146264

(51) Int. Cl. H05K 7/20

(52) U.S. Cl. CPC H05K 7/2039

(57) ABSTRACT

An optical transceiver module housing includes a housing body and a heat sink. The housing body has an electronic component accommodating space and an opening communicated with the electronic component accommodating space. The heat sink is detachably assembled to the housing body, and includes a thermally conductive plate and at least one thermally conductive fin fixed on the thermally conductive plate. The thermally conductive plate is accommodated in the electronic component accommodating space. The at least one thermally conductive fin is exposed from the opening. An Optical transceiver module includes a circuit board assembly and the above optical transceiver module housing. The circuit board assembly has a board edge connector. The circuit board assembly is accommodated in the electronic component accommodating space and extends out of the electronic device accommodating space to expose the board edge connector. The thermally conductive plate is thermally coupled with the circuit board assembly.

### BACKGROUND OF THE INVENTION

### 1. FIELD OF THE INVENTION

The present invention relates to an optical transceiver module, and more particularly to an optical transceiver module with a heat-dissipating structure.

### 2. DESCRIPTION OF THE PRIOR ART

In the field of optical communications, the transmission rate of optical transceiver modules continues to increase, and the power of optical transceiver modules during operation also increases, causing the optical transceiver modules to often operate at higher temperatures. In order to prevent the operating temperature from being too high, some optical transceiver modules are currently equipped with heat dissipation fins on the module housing to effectively dissipate internal heat. However, this architecture in which the internal heat is first conducted to the module housing and then dissipated through the outer heat dissipation fins has gradually been unable to meet the usage scenarios with continuously increasing transmission rates, resulting in a design bottleneck for optical transceiver modules.

### SUMMARY OF THE INVENTION

An objective of the invention is to provide an optical transceiver module housing, which has a heat sink passing through its housing body, thereby directly absorbing heat energy inside the housing body and dissipating the absorbed heat energy to the outside of the housing body, thereby increasing heat dissipation efficiency.

An optical transceiver module housing of an embodiment according to the invention includes a housing body and a heat sink. The housing body has an electronic component accommodating space and an opening communicated with the electronic component accommodating space. The heat sink is detachably assembled to the housing body. The heat sink includes a thermally conductive plate and at least one thermally conductive fin fixed on the thermally conductive plate. The thermally conductive plate is accommodated in the electronic component accommodating space. The at least one thermally conductive fin is exposed from the opening. Thereby, the heat sink can directly absorb heat energy inside the housing body and dissipate the absorbed heat energy to the outside of the housing body, thereby increasing the heat dissipation efficiency.

Another objective of the invention is to provide an optical transceiver module, which includes the aforementioned optical transceiver module housing. Therefore, its heat sink can pass through the housing body to be directly thermally coupled with a heating component accommodated in the housing body, thereby increasing the heat dissipation efficiency.

An optical transceiver module of an embodiment according to the invention includes a circuit board assembly and the aforementioned optical transceiver module housing. The circuit board assembly has a board edge connector. The circuit board assembly is accommodated in the electronic component accommodating space and extends out of the electronic component accommodating space to expose the board edge connector. The thermally conductive plate is thermally coupled with the circuit board assembly. Thereby, the heat sink can directly absorb heat energy inside the housing body and dissipate the absorbed heat energy to the outside of the housing body, thereby increasing heat dissipation efficiency.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating an optical transceiver module according to an embodiment.

FIG. 2 is a partially-exploded view of the optical transceiver module in FIG. 1.

FIG. 3 is a sectional view of the optical transceiver module along the line X-X in FIG. 1.

FIG. 4 is a top view of an upper heat sink of an optical transceiver module housing of the optical transceiver module in FIG. 2.

FIG. 5 is a top view of a lower heat sink of the optical transceiver module housing of the optical transceiver module in FIG. 2.

FIG. 6 is a schematic diagram illustrating an optical transceiver module according to another embodiment.

### DETAILED DESCRIPTION

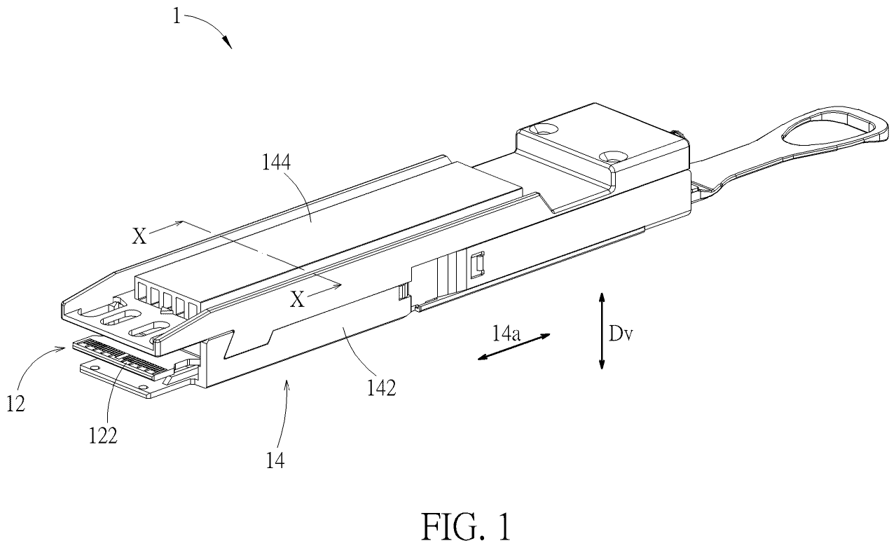

Please refer to FIG. 1 to FIG. 3. An optical transceiver module 1 according to an embodiment includes a circuit board assembly 12 and an optical transceiver module housing 14. The circuit board assembly 12 is accommodated in the optical transceiver module housing 14. The circuit board assembly 12 has a board edge connector 122, which is exposed out of the optical transceiver module housing 14 so as to be able to engage with a connector socket (not shown in the figure) of an optical transceiver module socket.

In the embodiment, the optical transceiver module housing 14 as a whole has a length direction 14a and includes a housing body 142 and two heat sinks (i.e., an upper heat sink 144 and a lower heat sink 146, respectively) detachably assembled to the housing body 142. The housing body 142 includes an upper cover 1422 and a lower cover 1424 in a vertical direction Dv (indicated by a double-headed arrow in the figures, perpendicular to the length direction 14a). The upper cover 1422 and the lower cover 1424 are connected to form an electronic component accommodating space 142a. The circuit board assembly 12 is accommodated in the electronic component accommodating space 142a and extends out of the electronic component accommodating space 142a to expose the board edge connector 122 in the length direction 14a. Therein, the upper cover 1422 and the lower cover 1424 have corresponding restraining structures to restrain long sides of a circuit board 120 of the circuit board assembly 12 (parallel to the length direction 14a). The upper cover 1422 has an opening 1422a in the vertical direction Dv, and the opening 1422a communicates with the electronic component accommodating space 142a; the lower cover 1424 also has an opening 1424a in the vertical direction Dv, and the opening 1424a communicates with the electronic component accommodating space 142a. The upper heat sink 144 is assembled to the upper cover 1422. The upper heat sink 144 partially extends into the electronic component accommodating space 142a through the opening 1422a and is exposed from the opening 1422a. The lower heat sink 146 is assembled to the lower cover 1424. The lower heat sink 146 partially extends into the electronic component accommodating space 142a through opening 1424a and is exposed from the opening 1424a. Both the upper heat sink 144 and the lower heat sink 146 are thermally coupled with the circuit board assembly 12 to directly absorb heat energy from the circuit board assembly 12 and dissipate the absorbed heat energy outside the housing body 142.

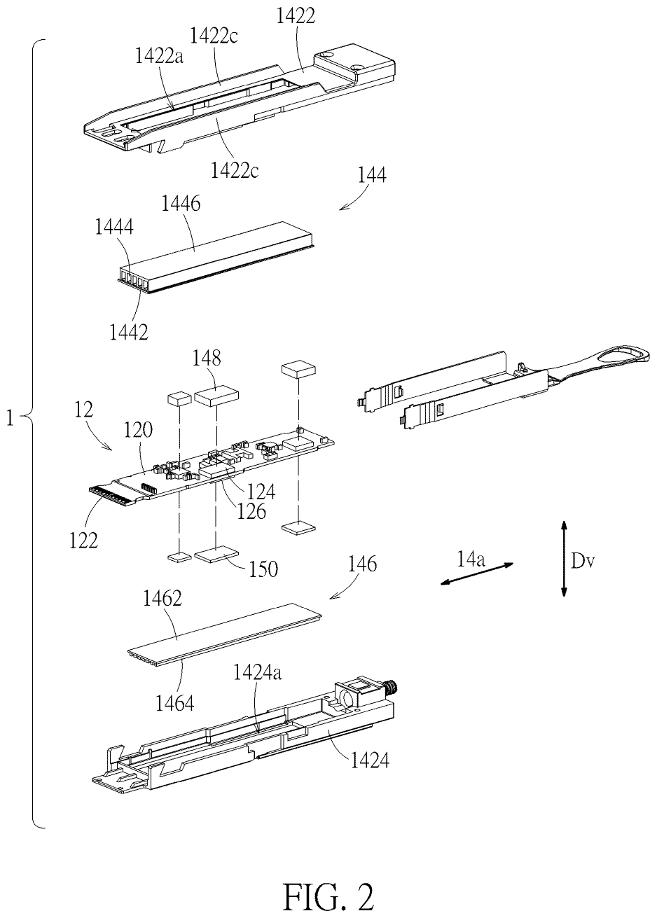

Please refer to FIG. 2 to FIG. 4; therein, FIG. 4 is a top view of the upper heat sink 144, in which the hidden profile of the upper heat sink 144 is shown in dashed lines. The upper heat sink 144 includes a thermally conductive plate 1442, at least one thermally conductive fin 1444 fixed on the thermally conductive plate 1442, and a cover plate 1446. The cover plate 1446 and the thermally conductive plate 1442 are disposed oppositely and fixedly connected to the at least one thermally conductive fin 1444. The thermally conductive plate 1442 is accommodated in the electronic component accommodating space 142a. The at least one thermally conductive fin 1444 is exposed from the opening 1422a of the upper cover 1422 and extends out of the housing body 142. The cover plate 1446 is located outside the housing body 142. The thermally conductive plate 1442 has a fin connecting portion 1442a (i.e., equivalent to the area enclosed by the frame in chain lines in FIG. 4) and a block portion 1442b (i.e., equivalent to the area between the frame in chain lines and the outline of the thermally conductive plate 1442 in FIG. 4, in the form of a rectangular frame). The at least one thermally conductive fin 1444 is connected to the fin connecting portion 1442a, and there are no fins on the block portion 1442b. The block portion 1442b is adjacent to the fin connecting portion 1442a and surrounds the fin connecting portion 1442a. The thermally conductive plate 1442 is larger than the opening 1422a of the upper cover 1422, so that the block portion 1442b is blocked within the electronic component accommodating space 142a by edges of the opening 1422a. In other words, the upper heat sink 144 will not detach from the housing body 142 from the opening 1422a, so that the highest position of the cover plate 1446 (i.e., the protruding height relative to upper cover 1422) can be controlled, which ensures that the external dimensions of the optical transceiver module housing 14 will comply with specifications. In actual assembly (from the viewpoint of FIG. 2), the upper heat sink 144 moves upward from under the upper cover 1422 to make part of the structure pass through the opening 1422a, and is then assembled to the upper cover 1422.

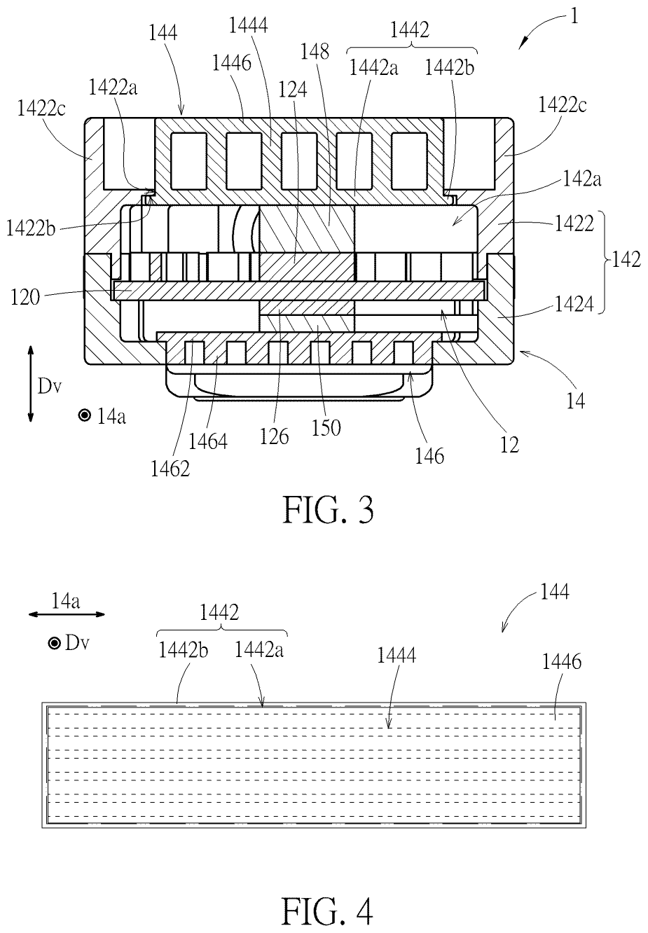

In addition, in the embodiment, the opening 1422a of the upper cover 1422 can be entirely projected on the heat conductive plate 1442 in the vertical direction Dv; however, it is not limited thereto in practice. For example, only part of the opening 1422a will be projected on the thermally conductive plate 1442 (e.g., the short sides of the block portion 1442b in the form of a rectangular frame are exposed from the opening 1422a, and the long sides of the block portion 1442b are still covered by the upper cover 1422); in this case, the block portion 1422b can still be effectively blocked by the edges of the opening 1422a, preventing the upper heat sink 144 from being separated from the housing body 142 from the opening 1422a. In addition, in practice, the block portion 1442b can be fixed on an inner surface 1422b of the upper cover 1422 (seeing FIG. 3), e.g., by gluing, soldering, screw locking, structural tight fitting, and so on.

Furthermore, as shown by FIG. 2 and FIG. 3, in the upper heat sink 144, the set number of the at least one heat conduction fin 1444 is six; however, it is not limited thereto in practice. The at least one thermally conductive fin 1444 extends parallel to the length direction 14a of the upper heat sink 144 (or the optical transceiver module 1) and is connected to and between the thermally conductive plate 1442 and the cover plate 1446, forming a plurality of air flow channels (parallel to the length direction 14a). These air flow channels allow airflow (such as cooling airflow for the equipment into which the optical transceiver module 1 is inserted) to flow through, which increases the heat dissipation efficiency of the thermally conductive fin 1444. In addition, the upper heat sink 144 is located between vertical plates 1422c on both sides of the top of the upper cover 1422. The upper heat sink 144 and the vertical plates 1422c are substantially the same height (relative to the top surface of the main body of the upper cover 1422). The top of the cover plate 1446 of the upper heat sink 144 is a flat surface, which is beneficial for the cover plate 1446 to contact the inner surface of the socket housing through its top after the optical transceiver module 1 is inserted into the socket, thereby increasing the heat dissipation efficiency.

As shown by FIG. 2 and FIG. 3, in the embodiment, the circuit board assembly 12 has a plurality of electronic components 124 (one of which is selected to be marked in the figures) on the side facing the upper heat sink 144. The thermally conductive plate 1442 is thermally coupled with the electronic component 124 through a thermal conductive material 148 (such as but not limited to a thermal conductive sheet), so that the thermally conductive plate 1442 can quickly absorb the heat generated by the electronic component 124 during operation to prevent the electronic component 124 from overheating, which may cause performance reduction or failure.

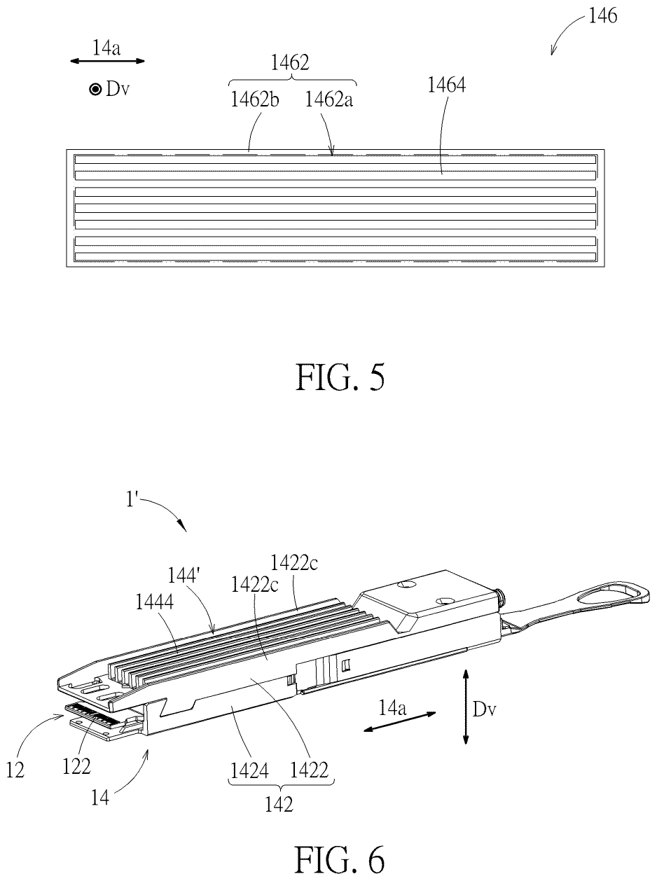

Please refer to FIG. 2, FIG. 3 and FIG. 5; therein, FIG. 5 is a top view of the lower heat sink 146. The lower heat sink 146 includes a thermally conductive plate 1462, and at least one thermally conductive fin 1464 (its set number is seven, but not limited thereto in practice) fixed on the thermally conductive plate 1462. The thermally conductive plate 1462 is accommodated in the electronic component accommodating space 142a. The at least one thermally conductive fin 1464 extends parallel to the length direction 14a and is exposed from the opening 1424a of the lower cover 1424. Similarly, the thermally conductive plate 1462 has a connecting portion 1462a (i.e., equivalent to the area enclosed by the frame in chain lines in FIG. 5) and a block portion 1462b (i.e., equivalent to the area between the frame in chain lines and the outline of the thermally conductive plate 1462 in FIG. 5, in the form of a rectangular frame). The at least one thermally conductive fin 1464 is connected to the fin connecting portion 1462a, and there are no fins on the block portion 1462b. The block portion 1462b is adjacent to the fin connecting portion 1462a and surrounds the fin connecting portion 1462a. The thermally conductive plate 1462 is larger than the opening 1424a of the lower cover 1424, so that the block portion 1462b is blocked within the electronic component accommodating space 142a by edges of the opening 1424a. In other words, the lower heat sink 146 will not detach from the housing body 142 from the opening 1424a, so that the position of the lower heat sink 146 relative to lower cover 1424 can be controlled, which ensures that the external dimensions of the optical transceiver module housing 14 will comply with specifications. In actual assembly (from the viewpoint of FIG. 2), the lower heat sink 146 moves downward from above the lower cover 1424 to make the at least one thermally conductive fin 1464 be located within the opening 1422a, and is then assembled to the lower cover 1424.

In addition, for other descriptions (including descriptions of variations) of the relative arrangement relationship between the thermally conductive plate 1462 and the opening 1424a, please refer directly to the previous description of the relative arrangement relationship between the thermally conductive plate 1442 of the upper heat sink 144 and the opening 1422a of the upper cover 1422, which will not be described in addition.

Furthermore, as shown by FIG. 2 and FIG. 3, the at least one thermally conductive fin 1464 of the lower heat sink 146 does not extend beyond the opening 1424a (i.e., not protrude from the bottom surface of the lower cover 1424), so during the insertion of the optical transceiver module 1 into the socket, the at least one thermally conductive fin 1464 will not interfere with the aforementioned insertion operation. In the embodiment, the end of the at least one thermally conductive fin 1464 is substantially coplanar with the bottom surface of the lower cover 1424; however, it is not limited thereto in practice.

Similarly, as shown by FIG. 2 and FIG. 3, in the embodiment, the circuit board assembly 12 has a plurality of electronic components 126 (one of which is selected to be marked in the figures) on the side facing the lower heat sink 146. The thermally conductive plate 1462 is thermally coupled with the electronic component 126 through a thermal conductive material 150 (such as but not limited to a thermal conductive sheet), so that the thermally conductive plate 1462 can quickly absorb the heat generated by the electronic component 126 during operation to prevent the electronic component 126 from overheating, which may cause performance reduction or failure.

As described above, in the optical transceiver module housing 14 of the optical transceiver module 1, the upper heat sink 144 and the lower heat sink 146 adopt a combined design and are combined with the upper cover 1422 and the lower cover 1424 respectively. Therefore, in practice, the upper heat sink 144, the lower heat sink 146, the upper cover 1422, and the lower cover 1424 can be made of different materials. For example, the upper cover 1422 and lower cover 1424 are made of zinc alloys to provide the required structural strength of optical transceiver module 1; the upper heat sink 144 and the lower heat sink 146 are made of aluminum alloys, which have higher heat dissipation efficiency (compared to zinc alloys). However, it is not limited thereto in practice. In addition, in the embodiment, the upper heat sink 144 has the cover plate 1446, and the lower heat sink 146 has the thermally conductive fin 1464; however, it is not limited thereto in practice. For example, as shown by FIG. 6, the upper heat sink 144′ of the optical transceiver module 1′ does not have an upper cover; in this case, the thermally conductive fin 1444 of the upper heat sink 144′is of the same height as the vertical plates 1422c. Furthermore, in the embodiment, the optical transceiver module housing 14 is provided with heat sinks (i.e., the upper heat sink 144 and the lower heat sink 146, respectively) on the upper and lower sides; however, it is not limited thereto in practice. For example, the optical transceiver module housing 14 is only provided with a heat sink on the upper side or the lower side (i.e., the upper heat sink 144 or the lower heat sink 146 is selectively provided).

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An optical transceiver module housing, comprising:
a housing body, the housing body having an electronic component accommodating space and an opening communicated with the electronic component accommodating space; and
a heat sink, the heat sink being detachably assembled to the housing body, the heat sink comprising a thermally conductive plate and at least one thermally conductive fin fixed on the thermally conductive plate, the thermally conductive plate being accommodated in the electronic component accommodating space, the at least one thermally conductive fin being exposed from the opening.

2. The optical transceiver module housing according to claim 1, wherein the at least one thermally conductive fin extends out of the housing body.

3. The optical transceiver module housing according to claim 1, wherein the heat sink comprises a cover plate, and the cover plate is disposed opposite to the thermally conductive plate and is fixedly connected to the at least one thermally conductive fin.

4. The optical transceiver module housing according to claim 1, wherein the thermally conductive plate has a fin connecting portion and a block portion, the block portion is adjacent to the fin connecting portion, and the block portion is blocked within the electronic component accommodating space by an edge of the opening.

5. The optical transceiver module housing according to claim 4, wherein the block portion surrounds the fin connecting portion.

6. The optical transceiver module housing according to claim 4, wherein the block portion is fixed to an inner surface of the housing body.

7. The optical transceiver module housing according to claim 1, wherein the housing body comprises an upper cover and a lower cover, the upper cover and the lower cover are connected to form the electronic component accommodating space, and the opening is disposed on the upper cover or the lower cover.

8. The optical transceiver module housing according to claim 1, wherein the housing body and the heat sink are made of different materials.

9. The optical transceiver module housing according to claim 1, wherein the at least one thermally conductive fin does not extend beyond the opening.

10. An optical transceiver module, comprising:
an optical transceiver module housing, the optical transceiver module housing comprising:
a housing body, the housing body having an electronic component accommodating space and an opening communicated with the electronic component accommodating space; and
a heat sink, the heat sink being detachably assembled to the housing body, the heat sink comprising a thermally conductive plate and at least one thermally conductive fin fixed on the thermally conductive plate, the thermally conductive plate being accommodated in the electronic component accommodating space, the at least one thermally conductive fin being exposed from the opening; and
a circuit board assembly, the circuit board assembly having a board edge connector, the circuit board assembly being accommodated in the electronic component accommodating space and extending out of the electronic component accommodating space to expose the board edge connector, the thermally conductive plate being thermally coupled with the circuit board assembly.

11. The optical transceiver module according to claim 10, wherein the circuit board assembly has an electronic component, and the thermally conductive plate is thermally coupled with the electronic component through a thermal conductive material.

12. The optical transceiver module according to claim 10, wherein the at least one thermally conductive fin extends out of the housing body.

13. The optical transceiver module according to claim 10, wherein the heat sink comprises a cover plate, and the cover plate is disposed opposite to the thermally conductive plate and is fixedly connected to the at least one thermally conductive fin.

14. The optical transceiver module according to claim 10, wherein the thermally conductive plate has a fin connecting portion and a block portion, the block portion is adjacent to the fin connecting portion, and the block portion is blocked within the electronic component accommodating space by an edge of the opening.

15. The optical transceiver module according to claim 14, wherein the block portion surrounds the fin connecting portion.

16. The optical transceiver module according to claim 4, wherein the block portion is fixed to an inner surface of the housing body.

17. The optical transceiver module according to claim 10, wherein the housing body comprises an upper cover and a lower cover, the upper cover and the lower cover are connected to form the electronic component accommodating space, and the opening is disposed on the upper cover or the lower cover.

18. The optical transceiver module according to claim 10, wherein the housing body and the heat sink are made of different materials.

19. The optical transceiver module according to claim 10, wherein the at least one thermally conductive fin does not extend beyond the opening.
